(19) United States
(12) Patent Application Publication
(10) Pub. No.: US 2023/0234522 A1
(43) Pub. Date: Jul. 27, 2023

(54) VEHICLE ANOMALY DETECTION DEVICE

(71) Applicants: AutoNetworksTechnologies, Ltd, .Yokkaichi-shi, Mie (JP); Sumitomo Wiring Systems, Ltd., Yokkaichi-shi, Mie (JP); Sumitomo Electric Industries, Ltd., Osaka-shi Osaka (JP)

(72) Inventor: Takahiro SAITO, Yokkaichi-shi, Mie (JP)

(21) Appl. No.: 17/999,009

(22) PCT Filed: May 6, 2021
(86) PCT No.: PCT/JP2021/017360

§ 371 Date: Nov. 16, 2022

(30) Foreign Application Priority Data
May 21, 2020 (JP) 2020-089143

(51) Int. Cl. B60R 16/033; G01R 31/58

(52) U.S. Cl. CPC B60R 16/033; G01R 31/58

(57) ABSTRACT

A vehicle anomaly detection device is used in a vehicle power system. The vehicle anomaly detection device includes a target wiring portion and an anomaly detection unit. The target wiring portion constitutes at least a portion of the inter-storage power path and is a target for anomaly detection. The anomaly detection unit performs a predetermined anomaly check operation on the target wiring portion and detects an anomaly in the target wiring portion based on the result of the anomaly check operation.

### CROSS-REFERENCE TO RELATED APPLICATIONS

This application is the U.S. national stage of PCT/JP2021/017360 filed on May 6, 2021, which claims priority of Japanese Patent Application No. JP 2020-089143 filed on May 21, 2020, the contents of which are incorporated herein.

### TECHNICAL FIELD

The present disclosure relates to a vehicle anomaly detection device.

### BACKGROUND

JP 2018-6252A discloses a relay device in a system that can supply power to a load using two power storage units, the relay device being capable of detecting an anomaly such as an open circuit in either of the power storage units.

In some vehicle power systems, power is supplied to a load from both a first power storage unit and a second power storage unit. When the load is connected to a common power path provided between the two power storage units in such a power system, even if an anomaly such as an open circuit occurs on the common storage path and one of the power storage units ceases to supply power to the load, the other power storage unit continues to supply power to the load. That is, even in the event of an anomaly occurring on the common power path, the load continues to operate without stopping. Thus, it is difficult to detect the anomaly by only monitoring the load.

An object of the present disclosure is to provide a technique for detecting an anomaly in a wiring unit on an inter-storage power path to which power can be supplied from a plurality of power storage units.

### SUMMARY

A vehicle anomaly detection device that is an aspect of the preset disclosure is a vehicle anomaly detection device for use in a vehicle power system including a first power storage unit, a second power storage unit, and an inter-storage power path that is provided between the first power storage unit and the second power storage unit, constitutes a path to which power is supplied from the first power storage unit, and constitutes a path to which power is supplied from the second power storage unit, the vehicle anomaly detection device including: a target wiring portion that constitutes at least a portion of the inter-storage power path and is a target for anomaly detection; and an anomaly detection unit that performs a predetermined anomaly check operation on the target wiring portion and detects an anomaly in the target wiring portion based on a result of the anomaly check operation.

### Advantageous Effects

The vehicle anomaly detection device which is an aspect of the present disclosure can detect an anomaly in the wiring unit on the inter-storage power path to which power can be supplied from the plurality of power storage units.

### BRIEF DESCRIPTION OF DRAWINGS

FIG. 1 is a block diagram schematically showing a vehicle power system that includes a vehicle anomaly detection device in a first embodiment.

FIG. 2 is a descriptive diagram showing the vehicle power system in FIG. 1 in a first load group and a second load group.

FIG. 3 is a block diagram showing the vehicle power system shown in FIG. 1 in detail.

FIG. 4 is a flowchart showing a flow of an anomaly detection process performed by the vehicle anomaly detection device in the first embodiment.

FIG. 5 is a block diagram showing, in detail, a vehicle power system that includes a vehicle anomaly detection device in another embodiment.

### DETAILED DESCRIPTION OF PREFERRED EMBODIMENTS

Hereinafter, aspects of the present disclosure will be listed and exemplified. The aspects (1) to (8) exemplified below may be combined in any manner provided no contradiction arises therebetween.

### First Aspect

A vehicle anomaly detection device in accordance with a first aspect is provided. The vehicle anomaly detection device is for use in a vehicle power system including a first power storage unit, a second power storage unit, and an inter-storage power path that is provided between the first power storage unit and the second power storage unit, constitutes a path to which power is supplied from the first power storage unit, and constitutes a path to which power is supplied from the second power storage unit. The vehicle anomaly detection device includes: a target wiring portion that constitutes at least a portion of the inter-storage power path and is a target for anomaly detection; and an anomaly detection unit that performs a predetermined anomaly check operation on the target wiring portion and detects an anomaly in the target wiring portion based on a result of the anomaly check operation.

If an anomaly occurs in the target wiring portion on the inter-storage power path to which power is supplied from both the first storage power part and the second storage power part, the vehicle anomaly detection device according to the first aspect can detect the anomaly in the target wiring portion using the anomaly detection unit.

### Second Aspect

In a second aspect of the vehicle anomaly detection device, the vehicle anomaly device according to the first aspect, the anomaly detection unit detects the anomaly in the target wiring portion using time domain reflectometry.

The vehicle anomaly detection device according to the second aspect can determine more accurately whether or not an anomaly such as a disconnection has occurred in the target wiring portion. For example, in the event of an anomaly causing a change in characteristic impedance of the target wiring portion, the vehicle anomaly detection device can detect the anomaly that would have been difficult to detect using an anomaly determination method in which a voltage is compared with a threshold or an anomaly determination method in which a current value is compared with a threshold.

### Third Aspect

In a third aspect, the vehicle anomaly detection device according to the first aspect or the second aspect, the anomaly detection unit performs the anomaly check operation at least while a vehicle equipped with the power system is travelling.

The vehicle anomaly detection device according to the third aspect can check whether or not the target wiring portion is properly functioning when power supply from one of the power storage units fails, while the vehicle is travelling. That is, in the event of an anomaly occurring in the target wiring portion while the vehicle is travelling, the vehicle anomaly detection device is highly likely to detect this anomaly, thus making it easier to promptly act upon the anomaly in the target wiring portion.

### Fourth Aspect

In a fourth aspect, the vehicle anomaly detection device according to any one of the first to the third aspects, the first power storage unit is installed on one side in a front-rear direction of the vehicle equipped with the power system, the second power storage unit is installed on the other side in the front-rear direction of the vehicle, and the target wiring portion is routed from a first position on the one side in the front-rear direction of the vehicle to a second position on the other side in the front-rear direction of the vehicle.

In the power system in which the first power storage unit and the second power storage unit can be arranged shifted from each other in the front-rear direction of the vehicle, the vehicle anomaly detection device according to the fourth aspect allows the target wiring portion to be routed over a wide area from the front side to the rear side of the vehicle, and is capable of inspecting the target wiring portion routed over a wide area.

### Fifth Aspect

In a fifth aspect, the vehicle anomaly detection device according to any one of the first to the fourth aspect, upon detecting an anomaly in the target wiring portion, the anomaly detection unit performs an operation of recording the occurrence of the anomaly in the target wiring portion to a recording medium or an operation of causing a notification unit to make a notification regarding the occurrence of the anomaly in the target wiring portion.

Even if the load supplied with power via the target wiring portion operates normally, in the event of an anomaly in the target wiring portion, the vehicle anomaly detection device according to the fifth aspect can record or make a notification regarding the occurrence of the anomaly to inform a user or the like. This allows the user or the like to recognize that there is an increased likelihood of a failure where a fault in one of the power storage units and an anomaly in the target wiring portion occur simultaneously, before the actual occurrence of such a failure, and take preventive measures in advance. Sixth Aspect

In a sixth aspect, the vehicle anomaly detection device according to any one of the first to the fifth aspects, the first power storage unit is installed on one side in a left-right direction of the vehicle equipped with the power system, the second power storage unit is installed on the other side in the left-right direction of the vehicle equipped with the power system, and the target wiring portion is routed from a position in the vehicle on the one side in the left-right direction to a position in the vehicle on the other side in the left-right direction.

In the power system in which the first power storage unit and the second power storage unit can be arranged in the vehicle shifted from each other in the left-right direction, the vehicle anomaly detection device according to the sixth aspect allows the target wiring portion to be routed over a wide area from the left side to the right side of the vehicle, and can inspect the target wiring portion routed over a wide area.

### Seventh Aspect

In a seventh aspect, the vehicle anomaly detection device according to any one of the first to the sixth aspects, the power system supplies power to a specific load connected to the inter-storage power path, and if a disconnection occurs in the target wiring portion between a branching position where the inter-storage power path branches to the specific load and one of the first power storage unit and the second power storage unit, the power supply from the other of the first power storage unit and the second power storage unit to the specific load is maintained.

In the power system in which the vehicle anomaly detection device according to the seventh aspect is used, even if a disconnection occurs in the target wiring portion on the path closer to one power storage unit relative to the branching position to the specific load, power is supplied from the other power storage unit to the specific load, and thus it is possible to prevent power to the specific load from being shut off. However, in this power system, since the specific load can continuously operate even in the event of a disconnection, the occurrence of the disconnection cannot be detected by only monitoring whether or not the specific load can operate. In contrast to this, the vehicle anomaly detection device according to seventh aspect can detect an anomaly in the target wiring portion using the anomaly detection unit, and thus can also detect a disconnection as described above.

### Eighth Aspect

In an eighth aspect, the vehicle anomaly detection device according to any one of the first to the seventh aspect, the power system includes: a first power path that is a path to which power is supplied from the first power storage unit; a second power path that is a power path branched from the first power path and a power path to which power is supplied from the first power storage unit and the second power storage unit; and a relay that switches a state between the first power path and the second power path between a conductive state and a shutoff state, wherein, when at least a first load is electrically connected to the first power path, at least a second load is electrically connected to the second power path, and at least the relay is off, no power is supplied from the second power storage unit to the first load and no power is supplied from the first power storage unit to the second load, and when operation of at least the first load is stopped, the second load executes the operation of the first load.

In the power system in which the vehicle anomaly detection device according to the eighth aspect is used, if a fault occurs in the first power storage unit or an anomaly (such as a ground fault) occurs on the first power path, the relay can be switched off to shut off the continuity between the first power path and the second power path, thereby protecting the second power path. In this configuration, when the relay is switched off so that only the second power storage unit supplies power to the second power path, if a disconnection or the like occurs in the target wiring portion, power will cease to be supplied to some or all of the loads. If this anomaly is not detected before the relay is switched off or the first power path or the first power storage unit becomes anomalous, a situation will occur where no protective operation can be performed properly. In contrast to this, the vehicle anomaly detection device according to in the eighth aspect can detect an anomaly in the target wiring portion in advance thus making a situation such as that described above unlikely to occur.

### First Embodiment

### 1. Overview of Power System

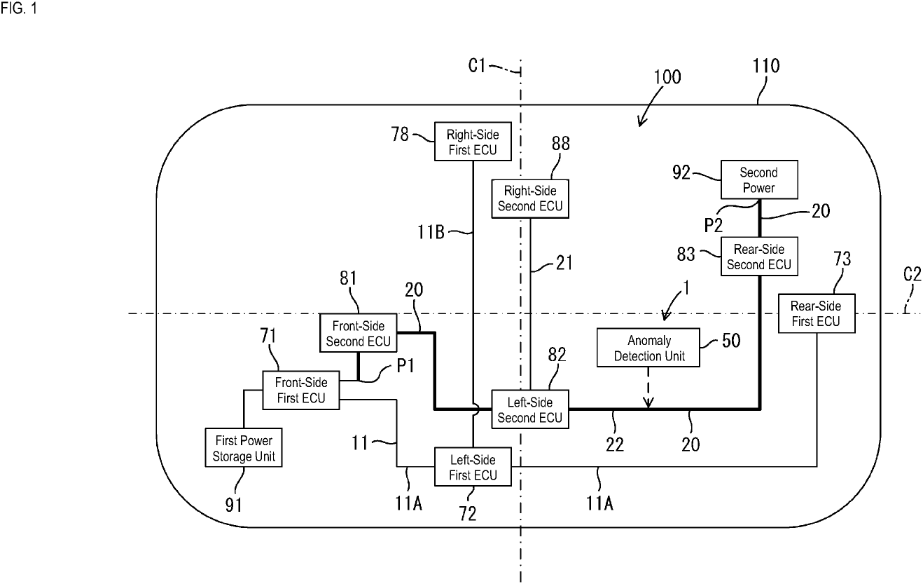

A vehicle power system 100 shown in FIG. 1 is a power system installed in a vehicle 110. In the following description, the vehicle power system 100 will also simply be referred to as the “power system 100”. The power system 100 includes a first power storage unit 91 and a second power storage unit 92, and is configured as a system that supplies power to various electric components provided in the vehicle 110.

The first power storage unit 91 functions as a main power source and is formed by a well-known power source such as a lead battery, for example. The first power storage unit 91 is not limited to a lead battery and may be any other kind of power storage unit that is configured in a chargeable and dischargeable manner. The first power storage unit 91 functions as a main battery that supplies power via a first power path 11. The first power storage unit 91 has a high-potential terminal that is electrically connected to the first power path 11 and configured to apply a DC voltage to the first power path 11. A low-potential terminal of the first power storage unit 91 is electrically grounded, for example.

The second power storage unit 92 is formed by a well-known power source such as a lithium-ion battery or an electrical double layer capacitor, for example. The second power storage unit 92 is not limited to a lithium-ion battery or an electrical double layer capacitor and may be any other kind of power storage unit that is configured in a chargeable and dischargeable manner. The second power storage unit 92 functions as a sub battery that supplies power via a second power path 12. The second power storage unit 92 has a high-potential terminal that is electrically connected to the second power path 12 and configured to apply a DC voltage to the second power path 12. A low-potential terminal of the second power storage unit 92 is electrically grounded, for example.

Although not shown in the drawings, a power generator may be provided so as to be electrically connected to the first power path 11 and be capable of supplying power to the first power path 11.

A relay 40 is a relay that switches the state between the first power path 11 and the second power path 12 between a conductive state and a shutoff state. When the relay 40 is on, the first power path 11 and the second power path 12 enter a conductive state in which power supply from the first power path 11 to the second power path 12 and power supply from the second power path 12 to the first power path 11 are allowed. When the relay 40 is off, the continuity between the first power path 11 and the second power path 12 is shut off and the power supply from the first power path 11 to the second power path 12 is shut off and the power supply from the second power path 12 to the first power path 11 is shut off.

The first power path 11 is a conductive path that is electrically connected to the first power storage unit 91 and is a path to which power is supplied from the first power storage unit 91. A DC voltage output from the first power storage unit 91 is applied to the first power path 11. The first power path 11 includes a main path 11A and a branched path 11B. The main path 11A is a conductive path that is electrically connected to the first power storage unit 91 and is routed over a wide area in the vehicle 110. A voltage that is based on the output voltage of the first power storage unit 91 is applied to the main path 11A. The branched path 11B is a conductive path that is branched from the main path 11A and is a conductive path to which a voltage equivalent to that of the main path 11A is applied.

The first power path 11 is a path used for supplying power from the first power storage unit 91 to a first load. The first load is a load that is electrically connected to the first power path 11 and is a load to which power from the first power storage unit 91 can be supplied when the relay 40 is off. That is, the first load is a load to which power from the first power storage unit 91 can be supplied even if no power is supplied from the second power storage unit 92 to the first power path 11. When the relay 40 is off, no power is supplied to the first load from the second power storage unit 92. FIGS. 1 to 3 show a front-side first electronic control unit (ECU) 71, a left-side first ECU 72, a rear-side first ECU 73, and a right-side first ECU 78 as examples of the first load. The front-side first ECU 71, the left-side first ECU 72, the rear-side first ECU 73, and the right-side first ECU 78 are configured as devices that function as gateways and control data communication, for example. The front-side first ECU 71, the left-side first ECU 72 the rear-side first ECU 73, and the right-side first ECU 78 are ECUs that can manage and control areas assigned thereto, and have a function of managing and controlling sensors and loads in the areas assigned thereto and a function of communicating with other ECUs.

Although not shown in the drawings, the first loads also include loads that can be controlled and managed by these ECUs. The first loads may include ignition-system loads such as a steering actuator, a shift by wire system, and an electronically controlled brake system. Alternatively, the first loads may include accessory-system loads such as a navigation device, an audio device, and an air conditioner. The first loads are not limited to these loads. Specifically, the first loads may include any other kind of ECU or may include loads other than an ECU.

The second power path 12 is a conductive path that is electrically connected to the second power storage unit 92 and is a conductive path to which a DC voltage output from the second power storage unit 92 is applied. The second power path 12 is a power path that is branched from the first power path 11 and is a power path to which power is supplied from the first power storage unit 91 and the second power storage unit 92. The second power path 12 includes an inter-storage power path 20 that is the main path and a conductive branched path 21 that is a branched path.

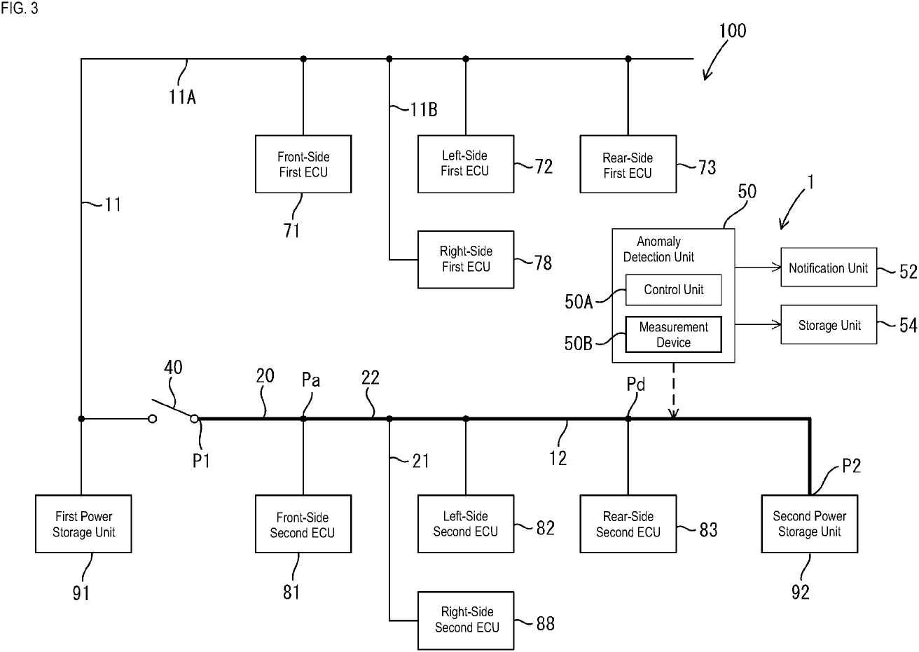

As shown in FIG. 3, the inter-storage power path 20 is a conductive path that is electrically connected to the second power storage unit 92 and is routed over a wide area in the vehicle 110 (FIG. 1). The inter-storage power path 20 is a conductive path that is provided between the first power storage unit 91 and the second power storage unit 92, constitutes a path to which power is supplied from the first power storage unit 91, and constitutes a path to which power is supplied from the second power storage unit 92. In the example shown in FIG. 3, one end of the inter-storage power path 20 is connected to the relay 40, and the other end is connected to the high-potential terminal of the second power storage unit 92. A voltage that is based on the output voltage of the second power storage unit 92 is applied to the inter-storage power path 20. The conductive branched path 21 is a conductive path that is branched from the inter-storage power path 20 and is a conductive path to which a voltage equivalent to that of the inter-storage power path 20 is applied.

The second power path 12 is a path that is used for supplying power from the second power storage unit 92 to the second load. The second load is a load that is electrically connected to the second power path 12 and is a load to which power from the second power storage unit 92 can be supplied when the relay 40 is off. That is, the second load is a load to which power from the first power storage unit 91 can be supplied even if no power is supplied from the second power storage unit 92 to the second power path 12. When the relay 40 is off, no power is supplied to the second load from the first power storage unit 91. The second load includes a redundant-system load that, if a predetermined load of the first loads ceases to function, executes the function of the predetermined load. FIGS. 1 to 3 show a front-side second ECU 81, a left-side second ECU 82, a rear-side second ECU 83, and a right-side second ECU 84 as examples of the second load. The front-side second ECU 81, the left-side second ECU 82, the rear-side second ECU 83, and the right-side second ECU 88 can manage or control corresponding areas in the vehicle. The second loads are redundant-system ECUs that, if the first load does not function, can execute the function of the first load in place of the first load. For example, the front-side second ECU 81 is an ECU that, if the front-side first ECU 71 does not function, can execute the function of the front-side first ECU 71 in place of the front-side first ECU 71. Similarly, the rear-side second ECU 83 is an ECU that, if the rear-side first ECU 73 does not function, can execute the function of the rear-side first ECU 73 in place of the rear-side first ECU 73.

Although not shown in the drawings, the second loads also include loads other than ECUs. The second loads may include ignition-system loads such as a steering actuator, a shift by wire system, and an electronically controlled brake system. For example, a shift by wire system serving as a second load is a redundant load that, if a shift by wire system serving as a first load does not function, functions as a shift by wire system in place of the shift by wire system serving as a first load. An electronically controlled brake system serving as a second load is a redundant-system load that, if an electronically controlled brake system serving as a first load does not function, functions as an electronically controlled brake system in place of the electronically controlled brake system serving as a first load. In this manner, at least some of the plurality of second loads are configured as redundant-system loads that, if an anomaly occurs where a first load stops operating, executes the operation of the first load in place of the first load. The second loads may include accessory-system loads.

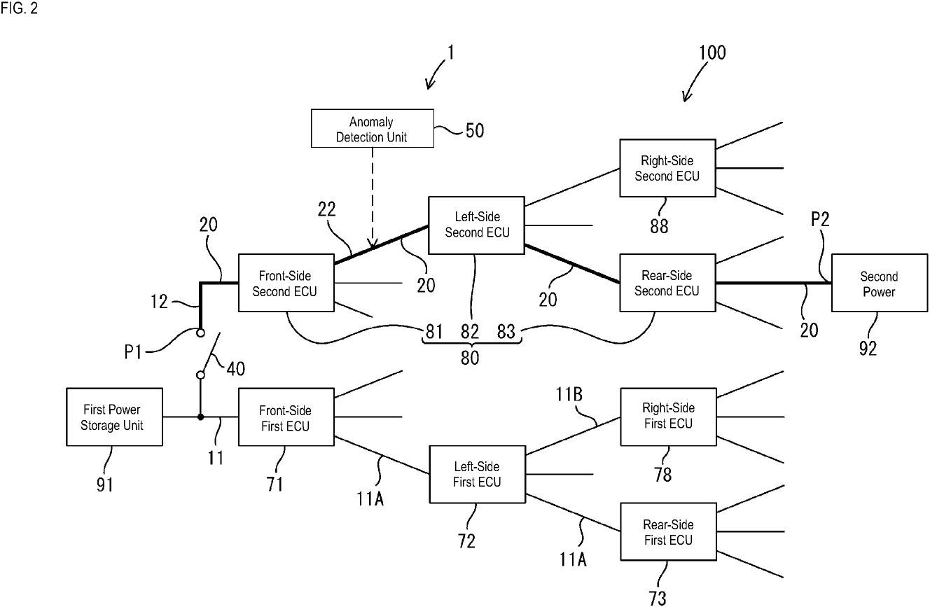

As shown in FIG. 2, the power system 100 can supply power to a specific load 80 connected to the inter-storage power path 20. In the examples shown in FIGS. 2 and 3, the front-side second ECU 81, the left-side second ECU 82, and the rear-side second ECU 83 correspond to examples of the specific load. As shown in FIGS. 2 and 3, in the power system 100, if a disconnection occurs in a target wiring portion 22 between a branching position where the inter-storage power path 20 branches to a specific load 80 and one of the first power storage unit 91 and the second power storage unit 92, power supply from the other of the first power storage unit 91 and the second power storage unit 92 to the specific load 80 is maintained. For example, if a disconnection occurs between a branching position Pa where the inter-storage power path 20 branches to the front-side second ECU 81 and the first power storage unit 91, power supply from the second power storage unit 92 to the front-side second ECU 81 is maintained. Alternatively, if a disconnection occurs between a branching position Pd where the inter-storage power path 20 branches to the rear-side second ECU 83 and the second power storage unit 92, power supply from the first power storage unit 91 to the rear-side second ECU 83 is maintained.

### 2. Details of Vehicle Anomaly Detection Device

A vehicle anomaly detection device 1 is a device that detects an anomaly in the wiring within the vehicle 110. The vehicle anomaly detection device 1 will be referred to as the “anomaly detection device 1” in the following description. The anomaly detection device 1 mainly includes the target wiring portion 22 and an anomaly detection unit 50.

The target wiring portion 22 constitutes at least a portion of the inter-storage power path 20 and is a target wiring portion for anomaly detection. In the example shown in FIG. 1, the first power storage unit 91 is installed on one side in the front-rear direction of the vehicle 110 equipped with the power system 100 (specifically, the front side), and the second power storage unit 92 is installed on the other side of the vehicle equipped with the power system 100 in the front-rear direction (specifically, the rear side). The target wiring portion 22 is routed from a first position P1 on the one side (front side) of the vehicle 110 in the front-rear direction to a second position P2 on the other side (rear side) of the vehicle 110 in the front-rear direction. In the present specification, the one side of the vehicle 110 in the front-rear direction means one side in the front-rear direction with respect to a central position C1 in the vehicle 110 in the front-rear direction, and specifically refers to the side forward of the central position C1 in the vehicle 110 in the front-rear direction. The other side of the vehicle 110 in the front-rear direction means the other side in the front-rear direction with respect to the central position C1 in the vehicle 110 in the front-rear direction, and specifically refers to the side rearward of the central position C1 in the vehicle 110 in the front-rear direction. The central position C1 is a central position where the distance from the central position to the front end of the vehicle 110 in the front-rear direction and the distance from the central position to the rear end of the vehicle 110 in the front-rear direction are equal.

In the example shown FIG. 1, the first power storage unit 91 is installed on one side in the left-right direction (specifically, the left side) of the vehicle 110 equipped with the power system 100, and the second power storage unit 92 is installed on the other side (specifically, the right side) of the vehicle 110 equipped with the power system 100 in the left-right direction. The target wiring portion 22 is routed from the first position P1 on one side in the left-right direction (left side) of the vehicle 110 to the second position P2 on the other side (right side) of the vehicle 110 in the left-right direction. In the present specification, the one side of the vehicle 110 in the left-right direction means one side of the vehicle 110 with respect to a central position C2 in the vehicle 110 in the left-right direction. The central position C2 is a central position where the width from the central position to the left end of the vehicle 110 in the left-right direction and the width from the central position to the right end of the vehicle in the left-right direction are equal.

The anomaly detection unit 50 is a device that performs a predetermined anomaly check operation on the target wiring portion 22. The anomaly detection unit 50 mainly has a control unit 50A and a measurement device 50B.

In the anomaly detection unit 50, the control unit 50A causes the measurement device 50B to perform a predetermined anomaly check operation in advance, and detects an anomaly in the target wiring portion 22 based on the results of the anomaly check operation performed by the measurement device 50B. Specifically, the measurement device 50B constituting a portion of the anomaly detection unit 50 measures a characteristic impedance of the target wiring portion 22 by using time domain reflectometry. Then, the control unit 50A detects an anomaly in the target wiring portion 22 based on the results of measurement of the characteristic impedance of the target wiring portion 22 performed by the measurement device 50B. Hereinafter, the time domain reflectometry will also be referred to as “TDR” .

The control unit 50A is configured as a control device that includes a computing unit such as a CPU, a storage unit such as a semiconductor memory, and a communication unit that communicates with an external device using a predetermined communication method, for example.

The measurement device 50B is configured as a device that measures the characteristic impedance of a transmission line by using time domain reflectometry.

The target wiring portion 22 is a target transmission line of which the characteristic impedance is to be inspected according to time domain reflectometry. One end of the target wiring portion 22 is located at the first position P1 and another end is arranged at the second position P2. The measurement device 50B measures the characteristic impedance of the target wiring portion 22 between the first position P1 and the second position P2 using TDR described above.

A notification unit 52 is a device that can perform a notification operation. The notification unit 52 may be configured as a display unit such as a lamp or a display device that displays a notification. The notification unit 52 may be constituted by a sound device such as a speaker that provides a notification using audio. The notification unit 52 may be constituted by a communication device that provides a notification by transmitting information to an external device. The notification unit 52 may include two or more of a display unit, a sound device, and a communication device.

A storage unit 54 includes a recording medium such as a semiconductor memory and is configured as a device that stores various types of information.

The following description relates to an anomaly detection process performed by the anomaly detection unit 50.

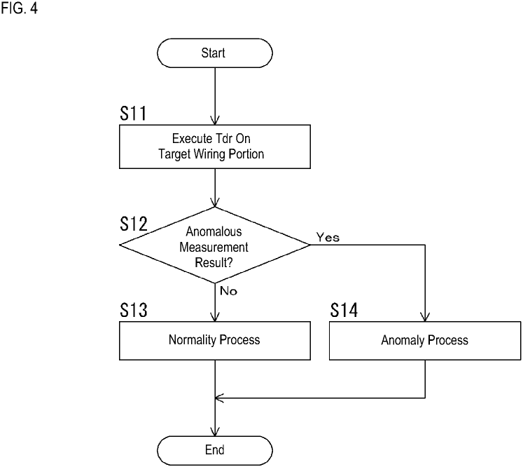

The control unit 50A of the anomaly detection unit 50 executes anomaly detection control shown in FIG. 4 when a predetermined start condition is satisfied. The predetermined start condition is not particularly limited. For example, the “predetermined start condition” may be that the start switch in the vehicle is turned on, or the “predetermined start condition” may be that power supply to the control unit 50A is started. Also, the “predetermined start condition” may be that a predetermined period of time has passed since termination of the previous anomaly detection process.

The control unit 50A operates so as to repeatedly execute the anomaly detection process shown in FIG. 4 while the vehicle is travelling. That is, the anomaly detection unit 50 repeatedly performs the anomaly check operation while the vehicle 110 equipped with at least the power system 100 is travelling, and determines whether or not the target wiring portion 22 is anomalous every time the anomaly check operation is executed. For example, the control unit 50A starts the anomaly detection process shown in FIG. 4 whenever a predetermined period of time has passed since termination of the previous anomaly detection process, while the vehicle is travelling.

At the start of the anomaly detection process shown in FIG. 4, the control unit 50A executes step S11 and instructs the measurement device 50B to perform a measurement operation. Upon receiving an instruction from the control unit 50A in step S11, the measurement device 50B measures the characteristic impedance of the target wiring portion 22 using time domain reflectometry. Specifically, the measurement device 50B injects a predetermined signal (high-speed pulse or step signal) to the target wiring portion 22 and observes the reflection waveform and transmission waveform of the signal, thereby measuring the characteristic impedance of the target wiring portion 22.

Based on the result of the measurement performed in step S11, the control unit 50A determines whether or not the measurement result is anomalous. Specifically, the control unit 50A determines whether the characteristic impedance of the target wiring portion 22 measured by the measurement device 50B using TDR in step S11 is within a predetermined normal range. If the control unit 50A determines in step S12 that the characteristic impedance of the target wiring portion 22 is within a predetermined normal range, that is, that the measurement result is not anomalous, the control unit 50Aperforms a predetermined normality process in step S13. The normality process may be a process for storing information indicating that the state of the target wiring portion 22 is normal as a log in the storage unit 54, or may be a process of making a notification to an external device indicating that the state of the target wiring portion 22 is normal.

If the control unit 50A determines in step S12 that the characteristic impedance of the target wiring portion 22 is not within the predetermined normal range, that is, that the measurement result is anomalous, the control unit 50A performs a predetermined anomaly process in step S14. The anomaly process may be a process for storing information indicating that the state of the target wiring portion 22 is anomalous as a log in the storage unit 54. Alternatively, the anomaly process may be a process for causing the display unit in the vehicle 110 to display the fact that the state of the target wiring portion 22 is anomalous or causing the notification unit 52 to perform a display operation. Otherwise, the anomaly process may be a process for causing the notification unit 52 to perform a communication operation of transmitting information indicating that the state of the target wiring portion 22 is anomalous to another device (for example, another ECU).

As described above, if the anomaly detection unit 50 detects an anomaly in the target wiring portion 22, the anomaly detection unit 50 performs an operation of recording the occurrence of the anomaly in the target wiring portion 22 to the storage unit 54 or an operation of causing the notification unit to provide a notification regarding the occurrence of an anomaly in the target wiring portion 22.

The following description relates to the advantageous effects of the first embodiment.

If an anomaly has occurred in the target wiring portion 22 on the inter-storage power path 20 to which power is supplied from both the first power storage unit 91 and the second power storage unit 92, the vehicle anomaly detection device 1 in the first embodiment can detect the anomaly in the target wiring portion 22 by using the anomaly detection unit 50.

In the vehicle anomaly detection device 1, the anomaly detection unit 50 detects an anomaly in the target wiring portion 22 using time domain reflectometry. The vehicle anomaly detection device 1 can determine more accurately and more reliably whether or not an anomaly such as a disconnection has occurred in the target wiring portion 22. For example, in the event of an anomaly causing a change in the characteristic impedance of the target wiring portion 22, the vehicle anomaly detection device 1 can detect the anomaly that would have been difficult to detect using an anomaly determination method in which a voltage is compared with a threshold or an anomaly determination method in which a current value is compared with a threshold.

In the vehicle anomaly detection device 1, the anomaly detection unit 50 can perform the anomaly check operation while the vehicle 110 equipped with the vehicle power system 100 is travelling. This vehicle anomaly detection device 1 can check whether or not the target wiring portion 22 is properly functioning when power supply from one of the power storage units fails, while the vehicle is travelling. That is, in the event of an anomaly occurring in the target wiring portion 22 while the vehicle 110 is travelling, the vehicle anomaly detection device 1 is highly likely to detect this anomaly, thus making it easier to promptly act upon the anomaly in the target wiring portion 22. The vehicle anomaly detection device 1 can make a situation less likely to occur where, when the supply of power from one power storage unit is interrupted while the vehicle 110 is travelling, a backup operation performed by the other power storage unit is hampered by an anomaly in the target wiring portion 22.

In the power system 100 in which the first power storage unit 91 and the second power storage unit 92 can be arranged shifted from each other in the front-rear direction in the vehicle 110, the vehicle anomaly detection device 1 allows the target wiring portion 22 to be routed over a wide area from the front to the rear side of the vehicle 110. The vehicle anomaly detection device 1 can more accurately inspect the widely arranged target wiring portion 22.

Even if the load supplied with power via the target wiring portion 22 operates properly, in the event of an anomaly in the target wiring portion 22, the vehicle anomaly detection device 1 can record or make a notification regarding the occurrence of the anomaly and inform a user or the like. This allows the user or the like to recognize that there is an increased likelihood of a failure where a fault in one of the power storage units and an anomaly in the target wiring portion 22 occur simultaneously, before the actual occurrence of such a failure, and take preventive measures in advance.

In the power system 100 in which the first power storage unit 91 and the second power storage unit 92 can be arranged shifted from each other in the left-right direction of the vehicle 110, the vehicle anomaly detection device 1 allows the target wiring portion 22 to be routed over a wide area from the left side to the right side of the vehicle 110. The vehicle anomaly detection device 1 can more accurately inspect the widely arranged target wiring portion 22.

In the power system 100, even if a disconnection occurs in the target wiring portion 22 on the path closer to one power storage unit relative to the branching position to the specific load 80, power is supplied from the other power storage unit to the specific load 80, and thus it is possible to prevent power supplied to the specific load 80 from being shut off. In this power system 100, however, since the specific load 80 can continuously operate even in the event of a disconnection, the occurrence of the disconnection cannot be detected by only monitoring whether or not the specific load 80 can operate. In contrast to this, the vehicle anomaly detection device 1 can detect an anomaly in the target wiring portion 22 using the anomaly detection unit 50, and thus can also detect a disconnection as described above.

In the power system 100 in which the vehicle anomaly detection device 1 is used, if a fault occurs in the first power storage unit 91 or an anomaly (such as a ground fault) occurs on the first power path 11, the relay 40 can be switched off to shut off the continuity between the first power path 11 and the second power path 12, thereby protecting the second power path 12. In this configuration, when the relay 40 is switched off so that only the second power storage unit 92 supplies power to the second power path 12, if a disconnection or the like occurs in the target wiring portion 22, power will cease to be supplied to some or all of the loads. If this anomaly is not detected before the relay 40 is switched off or the first power path 11 or the first power storage unit 91 becomes anomalous, a situation will occur where no protective operation can be performed properly. In contrast to this, the vehicle anomaly detection device 1 can detect an anomaly in the target wiring portion 22 in advance so that a situation such as that described above is unlikely to occur.

### Other Embodiments

The present disclosure is not limited to the embodiment described above and shown in the drawings. For example, the features of the embodiments described above or below can be combined provided no contradiction arises therebetween. Any of the features of the embodiments described above or below can be omitted unless it is clearly specified as being essential. The foregoing embodiment may be changed as follows.

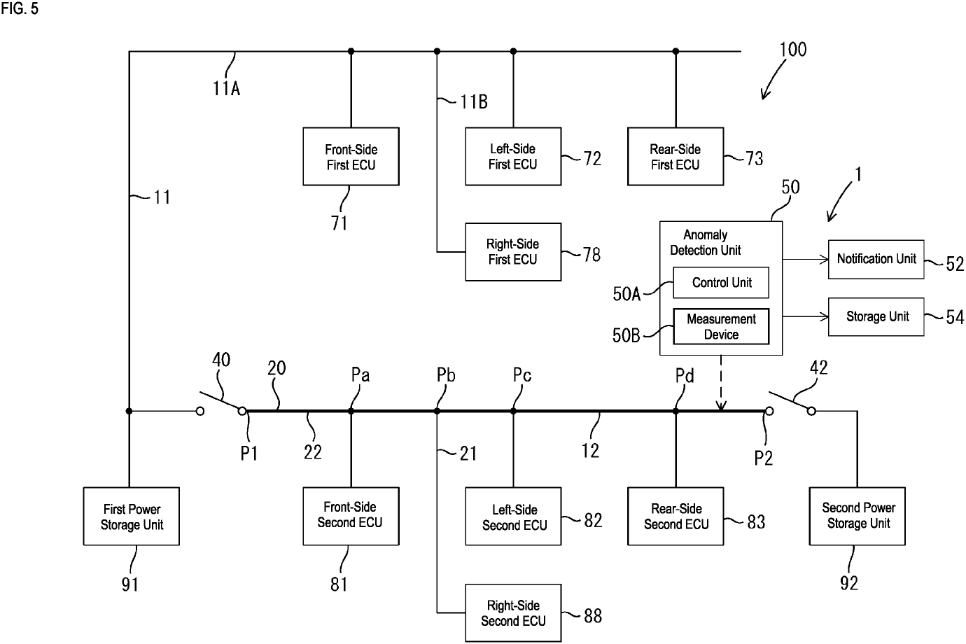

In the foregoing embodiment, the vehicle power system 100 configured as shown in FIGS. 1 to 3 is exemplified and the vehicle anomaly detection device 1 for use in the power system 100 is exemplified. However, the present disclosure is not limited to these exemplifications. For example, as shown in FIG. 5, a relay 42 different from the relay 40 may be provided on the inter-storage power path 20. Otherwise, in the configuration shown in FIGS. 3 or 5, a fuse may be provided on the first power path and the second power path.

In the foregoing embodiments, a method for determining an anomaly in the target wiring portion 22 using TDR is exemplified. However, the present disclosure is not limited to this method. For example, in the configuration as shown in FIG. 5, when the relay 40 is off and the relay 42 is on, if the voltage at any of a position Pa, a position Pb, a position Pc, and a position Pd is equal to or lower than a threshold voltage, the target wiring portion 22 may be determined as being anomalous. Similarly, when the relay 42 is off and the relay 40 is on, if the voltage at any of the position Pa, the position Pb, the position Pc, and the position Pd is equal to or lower than a threshold voltage, the target wiring portion 22 may be determined as being anomalous.

It should be considered that the embodiments disclosed herein are exemplifications and not limiting. It should be noted that the scope of the present disclosure is not limited to the examples herein, but rather is indicated by the scope of claims, and is intended to include all modifications within the meaning and scope equivalent to the scope of claims.

1. A vehicle anomaly detection device for use in a vehicle power system including a first power storage unit, a second power storage unit, and an inter-storage power path that is provided between the first power storage unit and the second power storage unit, constitutes a path to which power is supplied from the first power storage unit, and constitutes a path to which power is supplied from the second power storage unit,
the vehicle anomaly detection device comprising:
a target wiring portion that constitutes at least a portion of the inter-storage power path and is a target for anomaly detection; and
an anomaly detection unit that performs a predetermined anomaly check operation on the target wiring portion and detects an anomaly in the target wiring portion based on a result of the anomaly check operation.

2. The vehicle anomaly detection device according to claim 1, wherein the anomaly detection unit detects the anomaly in the target wiring portion using time domain reflectometry.

3. The vehicle anomaly detection device according to claim 1, wherein the anomaly detection unit performs the anomaly check operation at least while a vehicle equipped with the power system is travelling.

4. The vehicle anomaly detection device according to claim 1, wherein the first power storage unit is installed on one side in a front-rear direction of the vehicle equipped with the power system,
the second power storage unit is installed on the other side in the front-rear direction of the vehicle, and
the target wiring portion is routed from a first position on the one side in the front-rear direction of the vehicle to a second position on the other side in the front-rear direction of the vehicle.

5. The vehicle anomaly detection device according to claim 1, wherein, upon detecting an anomaly in the target wiring portion, the anomaly detection unit performs an operation of recording the occurrence of the anomaly in the target wiring portion to a recording medium or an operation of causing a notification unit to make a notification regarding the occurrence of the anomaly in the target wiring portion.
